(19) United States
(12) Patent Application Publication
(10) Pub. No.: US 2003/0006146 A1
(43) Pub. Date: Jan. 9, 2003

(54) Method for machining micro grooves of dynamic pressure pneumatic bearing

(76) Inventors: Eun-Sang Lee, Seoul (KR); Jeong-Woo Park, Pusan (KR); Chan-Hee Won, Daejeon (KR)

Correspondence Address: NOTARO & MICHALOS P.C., Empire State Building, Suite 6902, 350 Fifth Avenue, New York, NY, 10118-0110, US

(21) Appl. No.: 10/046,503

(22) Filed: Jan. 14, 2002

(30) Foreign Application Priority Data
Jul. 4, 2001 (KR) 2001-39647

(51) Int. Cl. B23H 11/00; B23H 3/00; B23H 5/00; C25F 7/00; B23H 7/00; B23H 9/00; C25F 3/00; H01L 21/00; H05K 3/07

(52) U.S. Cl. 205/640

(57) ABSTRACT

A method for forming and polishing micro grooves in a dynamic pressure pneumatic bearing at a short time by employing the electrolytic polishing process and the micro electrolytic machining process is disclosed. The method comprises the step of forming a plurality of micro grooves in a surface of the bearing using an electrochemical electrolytic polishing process and, an electrolytic machining process.

### BACKGROUND OF THE INVENTION

1. Field of the Invention

The present invention relates to a method for manufacturing a dynamic pressure pneumatic bearing, and more particularly, to an electrochemical multi-step machining method for defining micro grooves of a thrust bearing or journal bearing and polishing a surface thereof using electrolytic polishing, cleaning and electrolytic machining.

2. Background of the Related Art

Generally, micro grooves of an internal surface of a dynamic pressure pneumatic bearing are limited to a shape and dimension thereof, due to the theoretical design. Specifically, it is difficult to define the micro grooves on the internal surface of the dynamic pressure pneumatic bearing by typical machining methods. The shape of the defined micro grooves does not coincide to that of the designed micro grooves. In addition, there is a need for a long time to define the micro grooves. Therefore, there is a drawback that the typical method is not proper to the mass production of the dynamic pressure pneumatic bearing.

In order to define the micro grooves on the internal surface of the dynamic pressure pneumatic bearing, a method such as grinding or lapping was used, but the machining time is significantly required. Recently, several methods comprising form rolling, sintering, etching, rolling, specific tools or the like have been proposed, but the methods provide several drawbacks when defining the micro grooves on the internal surface of the dynamic pressure pneumatic bearing. According to the theoretical design, in case that the groove has a rectangular shape and a depth of below 10 μm, the dynamic pressure pneumatic bearing shows the stable rotating performance.

The conventional machining methods for manufacturing the dynamic pressure pneumatic bearing are as follows.

Since the surface machined by the form rolling has a triangle shape, it is difficult to generate a dynamic pressure. The shape of the surface machined by the etching is irregular, and remarkable time and cost of the machining are required. The formation of micro grooves using the sintering and rolling can be easily performed. However, the former cannot define a herringbone pattern of micro grooves on the internal surface of the dynamic pressure pneumatic bearing, and the letter forms protrusions around the grooves, thereby exerting a bad influence upon the rotating performance of the bearing. Accordingly, the methods may not provide the mass production due to the above drawbacks.

### SUMMARY OF THE INVENTION

Accordingly, the present invention is directed to a method for machining micro grooves of a dynamic pressure pneumatic bearing that substantially obviates one or more problems due to limitations and disadvantages of the related art.

An object of the present invention is to provide a method for forming and polishing micro grooves in a dynamic pressure pneumatic bearing at a short time by employing the electrolytic polishing process and the micro electrolytic machining process.

Another object of the present invention is to provide a method for forming and polishing micro grooves in a dynamic pressure pneumatic bearing capable of improving the quality of a workpiece and increasing the efficiency.

To achieve the object and other advantages and in accordance with the purpose of the invention, as embodied and broadly described herein, there is provided a method of machining a dynamic pressure pneumatic bearing, the method comprising the step of: forming a plurality of micro grooves in a surface of the bearing using an electrochemical electrolytic polishing process and an electrolytic machining process.

Preferably, the forming step is performed in order of an electrolytic polishing step, a cleaning step, and an electrolytic machining step, in order of an electrolytic machining step, a cleaning step, and an electrolytic polishing step, or in order of a primary electrolytic polishing step, a cleaning step, an electrolytic machining step, a cleaning step, and a secondary electrolytic polishing step.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 to 3 are flowcharts illustrating a method for machining a dynamic pressure pneumatic bearing according to first to third embodiments of the present invention, respectively.

FIG. 4 is a view illustrating the system for performing the method of machining the dynamic pressure pneumatic bearing shown in FIGS. 1 to 3.

FIGS. 5a and 5b are views perspectively illustrating a shape of an electrode and a process for polishing a thrust portion and a journal portion.

FIG. 6 is a view perspectively illustrating a process for simultaneously polishing a thrust portion and a journal portion.

FIGS. 7a and 7b are views illustrating an electrode for manufacturing a journal bearing housing with a herringbone pattern.

FIG. 8 is a view illustrating an electrode for manufacturing a thrust bearing.

### DETAILED DESCRIPTION OF THE PREFERRED EMBODIMENTS

Reference will now be made in detail to the preferred embodiment of the present invention, examples of which are illustrated in the accompanying drawings.

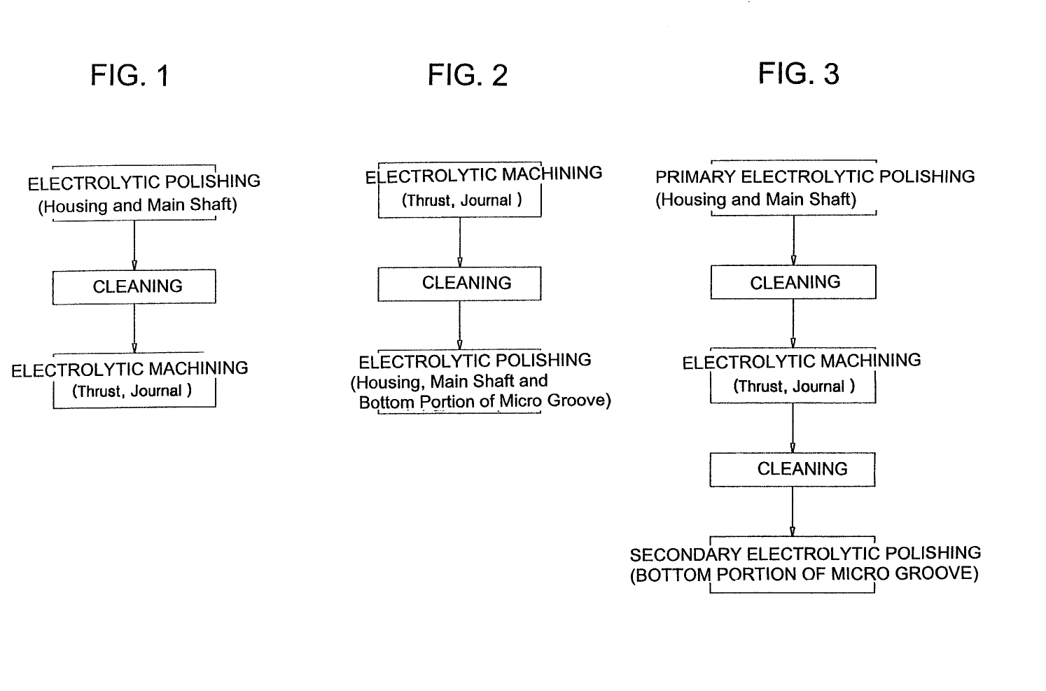

A method for manufacturing a dynamic pressure pneumatic bearing according to the present invention is illustrated in FIGS. 1 to 3, and the detail description will now be described by reference to the figures.

FIG. 1 shows a multi-step machining method sequentially performing an electrolytic polishing step, a cleaning step and an electrolytic machining step on thrust and journal portions. FIG. 2 shows another multi-step machining method sequentially performing an electrolytic machining step, a cleaning step and an electrolytic machining step on the thrust and journal portions, thereby obtaining a mirror surface on an internal surface of a housing or on an external peripheral surface of a main shaft of a bearing and on the vicinity of a bottom of the micro grooves. FIG. 3 shows still another multi-step machining method sequentially performing a primary electrolytic polishing step for obtaining a mirror surface on the internal surface of the housing or the external peripheral surface of the main shaft, a secondary electrolytic machining step to define the micro grooves, and an electrolytic polishing step for obtaining a mirror surface on the vicinity of a bottom portion of the micro grooves and for removing impurities.

When the dynamic pressure pneumatic bearing operates, the main shaft rotates within the bearing housing, with a gap between the main shaft and the bearing housing maintained in a level of 3 μm. The bearing is levitated by a pumping effect, which is caused by the dynamic pressure produced between the external peripheral surface of the main shaft and the housing. Either of the external peripheral surface of the main shaft or the internal surface of the housing is provided with a plurality of micro grooves of approximately 10 μm. The construction minimizes the friction between the housing and the main shaft, thereby maximizing the rotating performance of compact electronics. Although it is important to define the micro grooves, if the contacted surface between the main shaft and housing is not polished in the mirror surface, there is a mechanical friction between the main shaft and the housing, thereby deteriorating the rotating performance.

In order to overcome the drawback, the system for machining the dynamic pressure pneumatic bearing of the present invention employs two electrochemical machining techniques comprising a micro electrolytic polishing process and an electrolytic machining process. In case of employing the electrolytic machining, the external peripheral surface of the main shaft or the internal surface of the housing is machined to obtain a mirror surface. In addition, a rough surface which is produced by excessively concentrated electrical current onto the bottom of the micro grooves is machined to obtain the mirror surface. The micro electrolytic machining is to form the micro grooves in the external peripheral surface of the trust or journal bearing or on the internal surface of the housing.

The above electrolytic polishing is to planarize micro recessed portions by selectively melting only convex portions of the micro recessed portions formed on the surface of the bearing, thereby obtaining the high gloss and improving the corrosion resistance. The micro electrolytic machining is to form the micro grooves in the surface of the bearing at a short time.

If two techniques are employed to manufacture the dynamic pressure pneumatic bearing, the above methods are performed by a single system, thereby achieving the high efficiency.

The present invention employs two processes: after an electrolytic polishing step, an electrolytic machining step is carried out; and after the electrolytic machining step, the electrolytic polishing step is carried out. In case of firstly carrying out the electrolytic polishing step, after the bearing is to be machined to have an outer diameter slightly larger than a desired diameter, it is carried out the electrolytic polishing step on the bearing. And then, after the bearing is cleaned to remove the electrolytic polishing solution existed on the surface thereof, it is carried out through the electrolytic machining step.

In case of firstly carrying out the electrolytic machining step, the micro grooves are machined to have a slightly deep depth, in view of a removed amount of a surface by the electrolytic polishing. Since the dynamic pressure pneumatic bearing is generally applied to the compact appliances, the dimension precision is very important. Generally, the electrolytic polishing step uses phosphoric acid-based, sulfuric acid-based or chromic acid-based electrolyte, while the micro electrolytic machining step uses neutral electrolyte such as sodium nitrate-based electrolyte or sodium chloride electrolyte. Accordingly, when carrying out each step, since the above processes use different composition of the electrolyte, it is necessary to clean the workpiece. The cleaning step is also carried out by a single system, which will be fully described below.

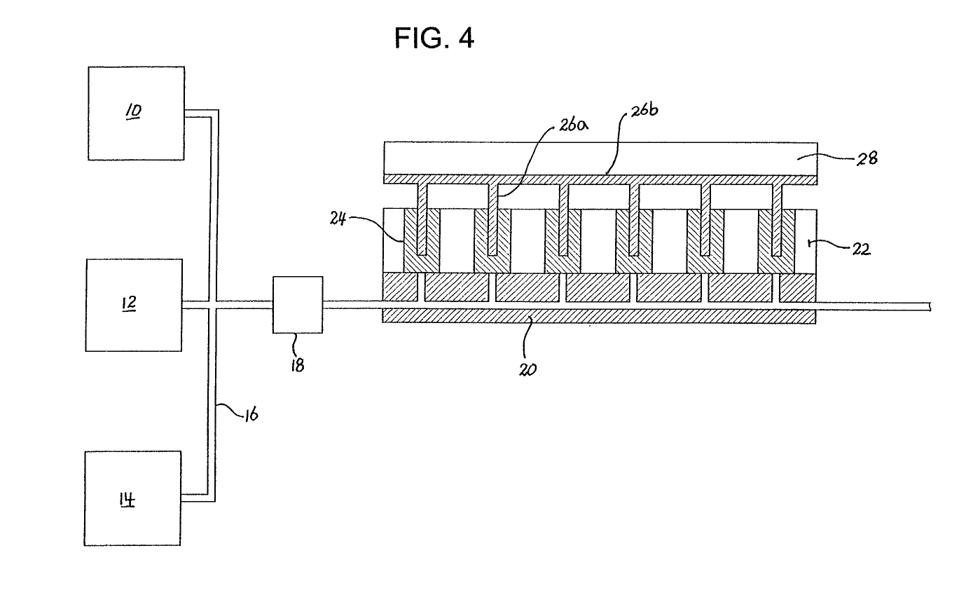

FIG. 4 shows the construction of the wholly system for performing a method for machining the dynamic pressure pneumatic bearing of the present invention. The system comprises three electrolyte storing tanks 10, 12 and 14 for storing a highly acidic electrolytic polishing solution, a middle acidic electrolytic machining solution, and a cleaning solution, respectively. The storing tanks 10, 12 and 14 are connected to an electrolyte circulating pipe 16 and a filter 18, as well as a valve and a pump (not shown). Further, the system comprises a bearing jig 20, electrolytic polishing and machining electrodes 26a and 26b, an electrolyte reservoir 22, an electrode supporting frame 28, and a power supply.

If the electrolytic polishing step is carried out by the system of the present invention, only electrolyte storing tank 10 for electrolytic polishing is opened, the electrolyte is supplied to the electrolyte reservoir 22 through the electrolyte supplying pipe 16 by the pump, thereby achieving the electrolysis operation. And then, the electrolyte is again supplied to the electrolyte storing tank 10 through an electrolyte discharging pipe to continuously perform the cycle, thereby obtaining a high level of surface polishing of the bottom surface of the micro grooves such as planarization, high gloss and corrosion resistance.

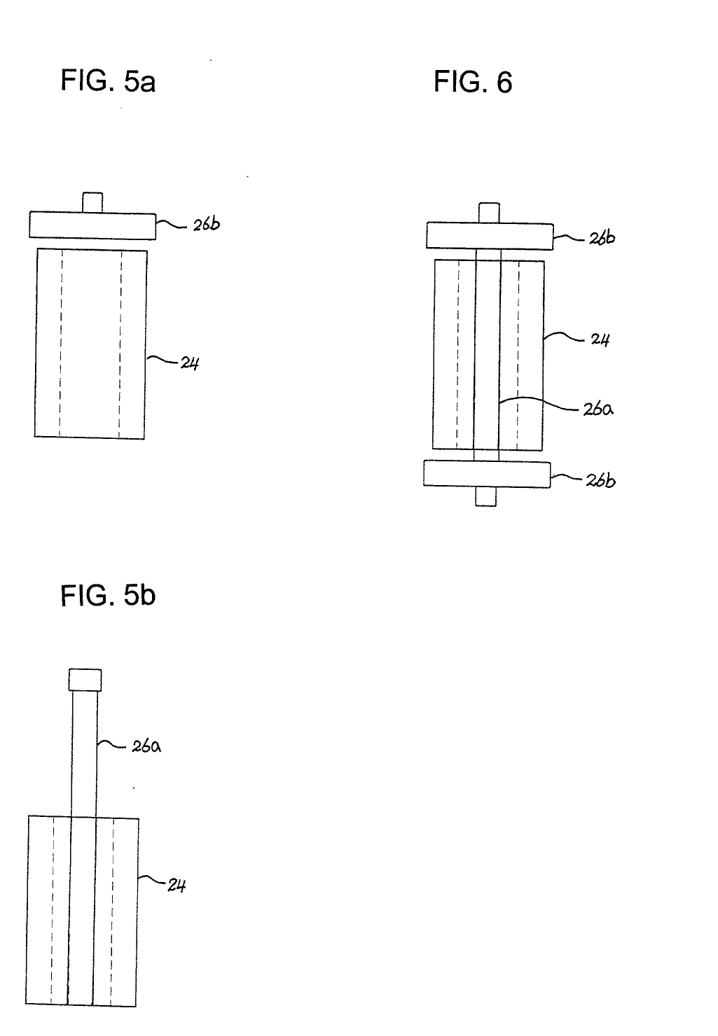

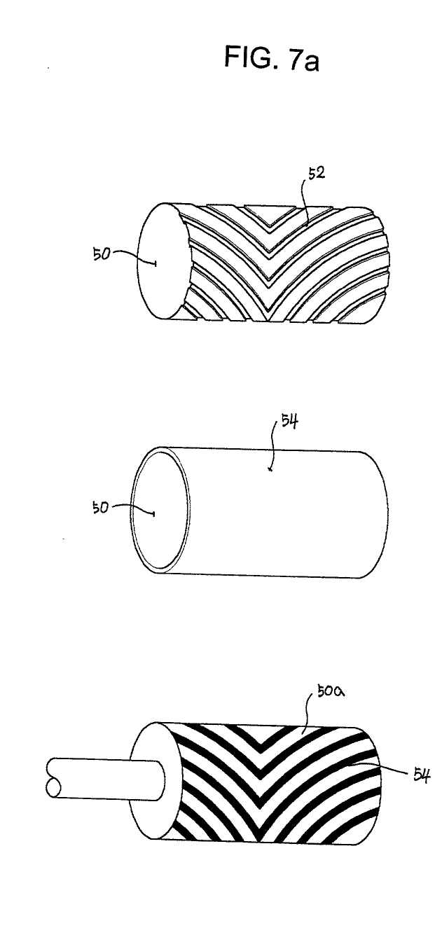

The electrodes 26a and 26b are made of brass, phosphor bronze or copper, as shown in FIGS. 5 and 6, and are transferred to a desired position so that a gap between the electrodes and the workpiece is constantly maintained in a range of 1 mm. The electrodes are supported by the electrode supporting frame 28 connected to a cathode of the power supply. An electrode typically used at the electrolytic machining process or a new electrode may be employed, each case illustrated in FIGS. 5 and 6. FIGS. 5a and 5b show a process for separately machining the thrust portion and the journal portion, and FIG. 6 shows a process for simultaneously machining the thrust portion and the journal portion.

After the electrodes 26a and 26b are machined to properly maintain the gap, the electrodes are inserted into the interior of the workpiece 24 and are positioned on a center thereof to evenly polish the surface of the bearing. Alternatively, if necessary, the internal or external surface of the bearing can be evenly polished by using a high electric current or the electrode for polishing the external surface. The electric power, which is applied to the electrode at the electrolytic polishing, is a direct current or a pulse electric power. In case of using the pulse electric power, it is a DC like-pulse, preferably a pulse having an On-time which is above 30% of an Off-time.

If the electric current is applied to the electrode during a predetermined time to take place the electrolytic polishing, the supply of the electric current from the power supply is cut off, and the electrolyte is sufficiently discharged to the electrolyte storing tanks 10, 12 and 14 through the electrolyte discharging pipe 16. A filter 18 for the electrolyte may be mounted onto an electrolyte feeding side or an electrolyte discharging side. The cleaning solution is circulated by opening a cleaning valve to sufficiently clean the electrolyte reservoir 22 and the jig 20, as well as the bearing of workpiece 24, thereby preparing the following micro electrolytic machining process for forming the micro grooves.

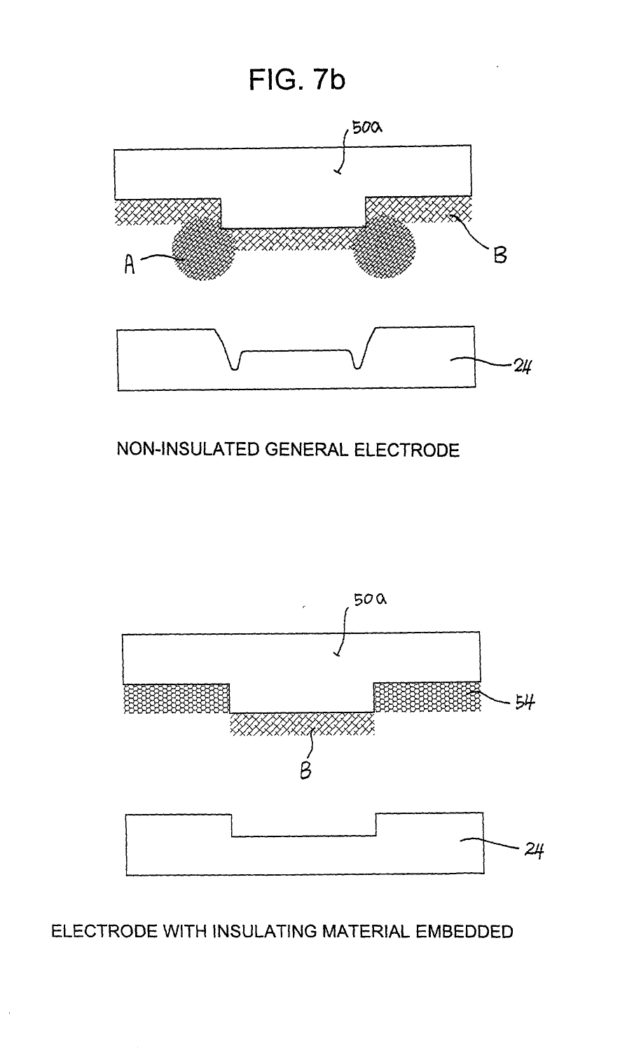

FIGS. 7a and 7b are views illustrating the shape of electrodes for manufacturing a journal bearing housing having a herringbone pattern on a surface thereof. Referring to FIG. 7a, the micro grooves 52 are formed in an external peripheral surface of the workpiece 50 by the precision machining. In order to prevent a leakage current, an insulating material 54 is applied on the entire surface of the workpiece 50. After the insulating material is completely solidified, the insulating material 54 is removed with a grinding machine until a surface of an electrode portion 50a is exposed. It is the reason that only micro grooves are electro-dissolved to form the micro grooves in the surface of the bearing and the unwanted dispersion of the current is prevented to give a rectangular shape to the micro grooves. Referring to FIG. 7b, a corner portion of the workpiece 24 is excessively electro-dissolved due to the current concentration onto a corner portion A of the electrode, and the current flows through a side of the electrode, so that the micro grooves does not has the rectangular shape. However, if the electrode 54 is insulated, the current flows evenly through only the surface thereof, thereby achieving the rectangular shape.

The workpiece 50 is made of brass, phosphor bronze or copper, as the description related with FIGS. 5 and 6. The workpiece 50 may be made of any material depending upon bearing manufacturers or the performance of the bearing.

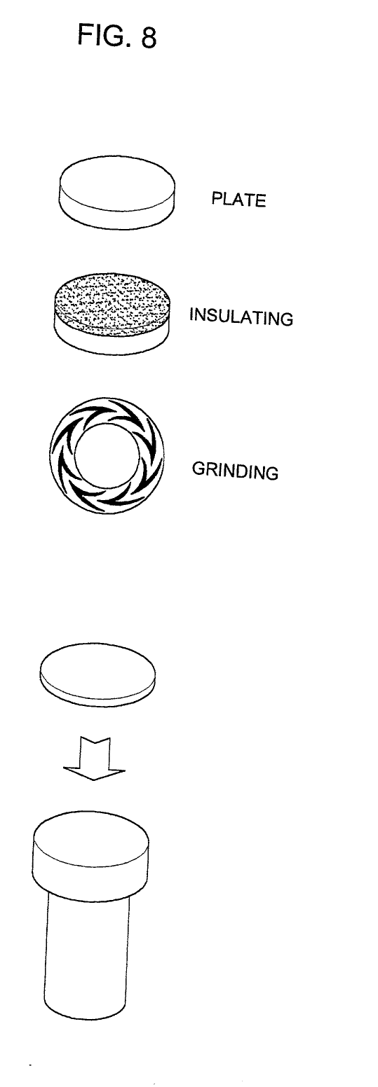

FIG. 8 is a view illustrating a process of manufacturing an electrode for machining a thrust bearing according to the present invention, in which since it is difficult to manufacture the electrode for the thrust bearing using the mechanical machining, only the surface of the electrode is separately manufactured using an etching process, and then is attached to a body of the electrode.

Since the micro grooves are easily formed using the etching process, the embodiment is proper to manufacture the electrode for machining the thrust bearing. A flat plate having a thickness of up to 1.0 mm is formed with a pattern corresponding to a shape of the electrode by the etching process, the pattern being penetrated through the plate or etched by about half thickness of the plate. After the plate is attached to the body of the electrode, like as the electrode for machining the journal bearing, an insulating material is applied to the electrode, and a surface of the insulating material is ground with a grinding machine, thereby manufacturing the electrode.

Like the above electrode polishing process, the electrode is disposed in the bearing housing at a proper gap, the electric power is applied to the electrode while the electrolyte is supplied. The condition of the electric power applied to the electrolytic machining is the use of a pulse power having a duty factor width within a range of 5 to 30%. It is the reason that the generation of hydrogen and heat is minimized during the electrolytic operation to achieve the micro machining. After 20 seconds of the current application, the formation of the micro grooves is completed. And then, after the current is cut off, the cleaning solution is circulated to clean the workpiece and the jig.

The electrolyte reservoir and the electrolyte storing tank have to be always maintained in a clean state, so that the electrolyte is not contaminated by adhesive or alien substance. In addition, in order to prevent the electro-dissolution due to the current leakage, the electrolyte reservoir and the electrolyte storing tank are made of PVC or acid resistance material.

In order to mass production, electrodes and workpiece jigs have a movable part, respectively, so that the gap therebetween can be adjusted. If the workpiece is in contact with the electrode, an alarm is operated to prevent an accident from happening. In addition, a flow controller is provided for controlling a flow rate of the electrolyte. The jig is made of titanium-based material having a superior corrosion resistance, by which the contacted mark produced at a contacted portion between the workpiece and the electrode when carrying out the electrolytic polishing process becomes to be small, and corroded mark is not produced around the contacted portion.

Examples of the present invention will now be described in detail, and the scope of the present invention is not restricted by the examples.

### EXAMPLE 1

In order to carry out an electrolytic polishing process for obtaining a mirror surface on an external surface of a housing and an internal surface of a main shaft, a solution consisting of 48% phosphoric acid (H₃PO₄), 19% sulfuric acid (H₂SO₄), and 33% distilled water (H₂O) was added with 15 grams of chromic acid. The mixture was supplied between an electrolytic polishing-electrolyte storing tank shown in FIG. 4 and a workpiece, and was applied with an electric current. STS304 of 3×6×10 mm (internal diameter×external diameter×height) was used as the workpiece. An electrode for polishing a journal portion had a diameter of 2 mm, and an electrode for polishing a thrust portion had a diameter of 7 mm. A velocity of the electrolyte supplied from the electrode was in a range of about 3 to 10 m/sec. If necessary, the electrolyte may be circulated with the workpiece dipped into the electrolyte. A gap between the workpiece and the electrode was set to 0.1 to 2 mm. A ratio of On-time/Off-time of a pulse was above 30%, a current density was about 0.1 to 10 A/cm², and a voltage was about 1 to 5 V.

When the above electrolytic polishing process was completed, the electrolyte was completely discharged, and the workpiece was cleaned. At that time, a cleaning solution was reverse osmosis (RO) water, and the cleaning process was performed by supplying the RO water (about 18 MΩ) at a speed of 3 to 10 m/sec during about 30 to 60 seconds to uniformly clean the workpiece and the electrode.

Next, when the cleaning process was completed, after the cleaning solution was sufficiently discharged. The electrode was replaced with an electrode (with an insulating material embedded into the electrode) for use in an electrolytic machining process to perform the electrolytic machining. A solution of 10 to 30% NaCl or NaNO₃ was supplied from the electrolyte storing tank shown in FIG. 4 to a gap between the workpiece and the electrode, and an electric current was applied to the solution. At that time, in order to give viscosity to the electrolyte, if necessary, 1 to 10% glycerin may be added to the electrolyte. The supplying velocity of the electrolyte was substantially similar to that of the electrolytic polishing process, while the electrolytic machining process was not performed through a dipping method. The electrode for electrolytic machining of journal portion had a diameter of 2.6 to 2.8 mm, while the electrode for electrolytic machining of thrust portion had a diameter of 7 mm. Since it is very important to maintain a gap between the electrode and the workpiece at constant intervals at the electrolytic machining process, the gap was maintained in a range of about 0.1 to 0.3. A ratio of On-time/Off-time of a pulse was below 30%, and a voltage was 8 to 20 V.

### EXAMPLE 2

The example was carried out in contrary to the procedure, i.e., order of electrolytic polishing and electrolytic machining, of the above example 1. Firstly, the electrolytic machining process was carried out under same condition as that of the electrolytic machining process in the example 1, and then the electrode and the workpiece were cleaned. In order to polish an internal and external surface of the workpiece and bottom surfaces of micro grooves to a mirror surface, the electrode was replaced with an electrode for electric polishing to perform the electrode polishing process. At that time, since corrosion may be happened at the bottom surface of the micro groove, the electrolytic polishing process was finally carried out to polish the bottom surface. The electrolytic polishing process was carried out under same condition as that of the example 1.

### EXAMPLE 3

As the examples 1 and 2, an internal surface of a housing or an external peripheral surface of a main shaft was primarily polished by an electrolytic polishing process to obtain a mirror surface. After cleaning the workpiece, the workpiece was carried out through the electrolytic machining process to form micro grooves. And then, the workpiece was secondarily carried out through the electrolytic polishing process to polish the mirror surface on a bottom portion of the micro groove which may be corroded at the electrolytic polishing process. When carrying out the electrolytic machining process, the electrode used at the primary electrolytic polishing was replaced with the electrode for electrolytic machining. When carrying out the secondary electrolytic polishing process, the electrode for electrolytic machining was used as it is because only the bottom portion of the micro portion was carried out through the electrolytic polishing.

With the present invention described above, at the dynamic pressure pneumatic bearing, the surface precision may be obtained at short time by employing the electrolytic polishing process and the micro electrolytic machining process.

In addition, the present invention can form a high precision of micro grooves. The electrolytic polishing process and the electrolytic machining process may be carried out at same time by a single system, as well as carrying out the cleaning process.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of machining a dynamic pressure pneumatic bearing, the method comprising the step of:
forming a plurality of micro grooves in a surface of the bearing using an electrochemical electrolytic polishing process and an electrolytic machining process.

2. The method as claimed in claim 1, wherein the forming step is performed in order of an electrolytic polishing step, a cleaning step, and an electrolytic machining step.

3. The method as claimed in claim 2, wherein the forming step is performed in order of an electrolytic machining step, a cleaning step, and an electrolytic polishing step.

4. The method as claimed in claim 1, wherein the forming step is performed in order of a primary electrolytic polishing step, a cleaning step, an electrolytic machining step, a cleaning step, and a secondary electrolytic polishing step.

5. The method as claimed in any one of claims 2 to 4, wherein the electrolytic polishing step comprises the steps of mixing a solution consisting of 40 to 50% phosphoric acid, 15 to 20% sulfuric acid, and 25 to 35% distilled water with 10 to 20 grams of chromic acid, supplying the mixed solution between a workpiece and an electrode, and applying an electric current to the mixed solution, thereby obtaining a mirror surface on an internal and external surface of a housing and a main shaft.

6. The method as claimed in any one of claims 2 to 4, wherein the electrolytic machining step comprises the steps of supplying a solution of 10 to 30% NaCl or NaNO₃ between a workpiece and an electrode, and applying an electric current to the mixed solution.

7. A method for manufacturing electrodes for a thrust portion and a journal portion, the method comprises the steps of:
applying an insulating material on a surface of the electrode;
solidifying the insulating material; and
removing the insulating material with a grinding machine, for exposing the surface of the electrode.

8. A method for manufacturing an electrode for a thrust portion, the method comprises the steps of:
forming a desired pattern on a surface of a thin plate using an etching process;
attaching the thin plate onto a body of the electrode; and
applying an insulating material onto the electrode.
